(19) United States
(12) Patent Application Publication
(10) Pub. No.: US 2026/0128749 A1
(43) Pub. Date: May 7, 2026

(54) METHOD AND NETWORK NODE FOR HANDLING TRANSMISSION OF NARROWBAND SIGNALS BETWEEN A RADIO PART AND A BASEBAND PART OF THE NETWORK NODE

(71) Applicant: Telefonaktiebolaget LM Ericsson (publ), Stockholm (SE)

(72) Inventors: Yang ZHANG, Sollentuna (SE); Oskar MAURITZ, Johanneshov (SE); Jing RAO, Sollentuna (SE)

(21) Appl. No.: 19/118,240

(22) PCT Filed: Oct. 6, 2022
(86) PCT No.: PCT/IB2022/059534

§ 371 Date: Apr. 3, 2025

(51) Int. Cl. H03M 7/30; H04L 1/20

(52) U.S. Cl. CPC H03M 7/6041; H03M 7/3059; H04L 1/20

(57) ABSTRACT

A method performed by a network node of a wireless communication network. The network node includes a radio part and a baseband part connected to the radio part via a communication interface, and has a plurality of antennas. The method includes obtaining, by the radio part, narrowband signals received at each of the plurality of antennas from a number of User Equipment, UE, wirelessly connected to the network node. The method further includes compressing, by the radio part, the obtained narrowband signals of the plurality of antennas so that the compressed narrowband signals as a group contains fewer number of bits than the obtained narrowband signals, wherein the compression is performed based on an individual compression error tolerance for each of at least some of the obtained narrowband signals, and sending, by the radio part, the compressed narrowband signals over the communication interface to the baseband part.

### TECHNICAL FIELD

The present disclosure relates generally to methods and network nodes in wireless communication networks for handling uplink narrowband signals to be transmitted from a radio part of the network node to a baseband part of the network node over an interface. The present disclosure further relates to computer programs and carriers corresponding to the above methods and radio parts.

### BACKGROUND

Wireless communication network bitrate demand continues to increase. To further improve radio link quality so that higher bitrate/spectrum efficiency can be achieved, 3GPP 5th Generation (5G) networks rely on massive Multiple Input Multiple Output (MIMO) and beamforming techniques to direct beams sent between a base station, aka network node, and a wireless device, aka User Equipment (UE), and thereby improve coverage. Beamforming is performed by coherently combining radio frequency (RF) signals from small antenna elements. By phase-shifting and/or amplifying the signal into the antenna elements, the desired beam is formed. These techniques mitigate the problem of path loss by radically increasing the beam gain, e.g., via constructive interference of multiple, relatively low power beams. Thereby, the rated Equivalent Isotropic Radiated Power (EIRP) rating of mmW base stations is restored to usable levels.

A network node that handles massive MIMO techniques is often realized as having a radio part and a baseband part interconnected via a communication interface, shortly “interface”. Functionality of the network node is split between the radio part and the baseband part. The radio part is connected to the plurality of antenna elements through which the network node wirelessly communicates with at least one UE.

In massive MIMO, a large amount of antenna elements is used, each antenna element receiving a version of an uplink (UL) signal sent from a UE. All those received antenna signals are to be transported over the communication interface between the radio part and the baseband part. In addition, a large bandwidth is used. All together this puts huge challenges on the communication interface between the radio part and the baseband part. In other words, the demand on capacity over the communication interface between the radio part and the baseband part increases. So, there is a need to try to limit the amount of data that is sent over this communication interface.

The radio part has a wideband receiver (WBR) for processing wideband signals. In addition, a narrowband receiver (NBR) for processing narrowband signals has been invented and inserted into the radio part to be used in e.g., an Advanced Antenna System (AAS) for various purposes. The NBR gives access to narrowband signals from the antenna elements with distributed beamforming. The NBR is designed for receiving and processing Physical Random-Access Channel (PRACH), Physical Uplink Control Channel (PUCCH), Sounding Reference Signal (SRS) and narrowband Physical Uplink Shared Channel (PUSCH) in parallel with the WBR processing UL payload data.

As shown, the interface load is dependent on both WBR and NBR data streams, at least in periods. Any method that can lower the interface load but still maintain signal quality has huge benefits.

### SUMMARY

It is an object of the invention to address at least some of the problems and issues outlined above. It is an object of embodiments of the invention to limit the interface load of an interface between a radio part and a baseband part of a network node. It is another object of embodiments to limit such interface load that depends on narrowband data streams or signals sent over the interface. It is possible to achieve these objects and others by using methods and network nodes as defined in the attached independent claims.

According to one aspect, a method is provided that is performed by a network node of a wireless communication network. The network node comprises a radio part and a baseband part connected to the radio part via a communication interface. The network node has a plurality of antennas. The method comprises obtaining, by the radio part, narrowband signals received at each of the plurality of antennas from a number of UEs wirelessly connected to the network node. The method further comprises compressing, by the radio part, the obtained narrowband signals of the plurality of antennas so that the compressed narrowband signals as a group contains fewer number of bits than the obtained narrowband signals, wherein the compression is performed based on an individual compression error tolerance for each of at least some of the obtained narrowband signals. The method further comprises sending, by the radio part, the compressed narrowband signals over the communication interface to the baseband part.

According to another aspect, a network node of a wireless communication network is provided. The network node comprises a radio part and a baseband part interconnected via a communication interface. The network node has a plurality of antennas. The network node comprises a processing circuitry and a memory. Said memory contains instructions executable by said processing circuitry, whereby the network node is operative for obtaining, by the radio part, narrowband signals received at each of the plurality of antennas from a number of UEs wirelessly connected to the network node. The network node is further operative for compressing, by the radio part, the obtained narrowband signals of the plurality of antennas so that the compressed narrowband signals as a group contains fewer number of bits than the obtained narrowband signals, wherein the compression is performed based on an individual compression error tolerance for each of at least some of the obtained narrowband signals, and sending, by the radio part, the compressed narrowband signals over the communication interface to the baseband part.

According to other aspects, computer programs and carriers are also provided, the details of which will be described in the claims and the detailed description.

Further possible features and benefits of this solution will become apparent from the detailed description below.

### BRIEF DESCRIPTION OF DRAWINGS

The solution will now be described in more detail by means of exemplary embodiments and with reference to the accompanying drawings, in which:

FIG. 1 is a schematic diagram of a wireless communication network in which the present invention may be used.

FIG. 2 is a flow chart illustrating a method performed by a network node, according to possible embodiments.

FIG. 3 is a flow chart illustrating another method performed by a network node, according to possible embodiments.

FIG. 4 is a block diagram of an embodiment of a radio part in which the present invention may be used.

FIG. 5 is a diagram of Signal to Noise Ratio (SNR) versus PRACH missed rate for a narrowband signal coded with 12, 4 or 2 bits, according to an illustrative example.

FIG. 6 is another diagram of Signal to Noise Ratio (SNR) versus PRACH missed rate for a narrowband signal coded with 12, 4 or 2 bits in which possible characteristics are shown, according to an illustrative example.

FIG. 7 is a block diagram illustrating a network node in more detail, according to further possible embodiments.

### DETAILED DESCRIPTION

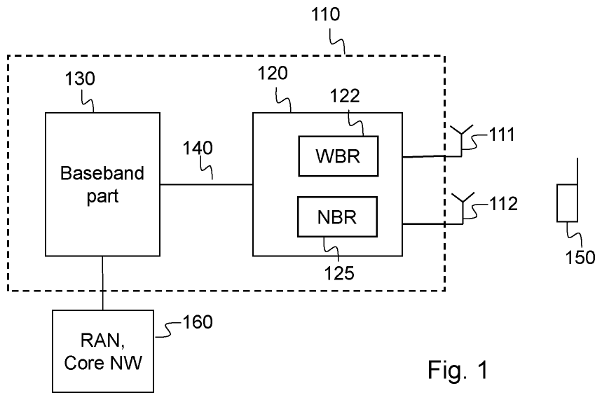

FIG. 1 shows a wireless communication network comprising a radio access network (RAN) node aka network node 110 that is in, or is adapted for, wireless communication with a wireless communication device aka wireless device or User Equipment (UE) 150. The network node 110 provides radio access in a cell covering a geographical area.

The wireless communication network may be any kind of wireless communication network that can provide radio access to wireless devices. Example of such wireless communication networks are networks based on Global System for Mobile communication (GSM), Enhanced Data Rates for GSM Evolution (EDGE), Universal Mobile Telecommunications System (UMTS), Code Division Multiple Access 2000 (CDMA 2000), Long Term Evolution (LTE), LTE Advanced, Wireless Local Area Networks (WLAN), Worldwide Interoperability for Microwave Access (WiMAX), WiMAX Advanced, as well as fifth generation (5G) wireless communication networks based on technology such as New Radio (NR), and any possible future sixth generation (6G) wireless communication network.

The network node 110 may be any kind of network node that can provide wireless access to a UE 150 alone or in combination with another network node. Examples of network nodes 110 are a base station (BS), a radio BS, a base transceiver station, a BS controller, a network controller, a Node B (NB), an evolved Node B (eNB), a gNodeB (gNB), a Multi-cell/multicast Coordination Entity, a relay node, an access point (AP), a radio AP, a remote radio unit (RRU), a remote radio head (RRH) and a multi-standard BS (MSR BS).

The wireless device 150 may be any type of device capable of wirelessly communicating with a network node 110 using radio signals. For example, the wireless device 150 may be a User Equipment (UE), a machine type UE or a UE capable of machine to machine (M2M) communication, a sensor, a tablet, a mobile terminal, a smart phone, a laptop embedded equipped (LEE), a laptop mounted equipment (LME), a USB dongle, a Customer Premises Equipment (CPE), an Internet of Things (IoT) device, etc.

The network node 110 comprises a radio part 120 and a baseband part 130 interconnected via a communication interface 140. The network node 110 has a plurality of antenna elements 111, 112 through which the network node can receive and transmit radio signals to/from the UE 150. The radio part 120 is connected to (and may comprise) the plurality of antenna elements 111, 112. Functionality of the network node 110 is split between the radio part 120 and the baseband part 130. The baseband part 130 handles signals when in baseband. The baseband part 130 may perform scheduling, link adaptation, coding/decoding, modulation/demodulation etc. The radio part 120 performs radio frequency handling of signals, such as analog-to-digital/digital-to-analog conversion, up/down conversion from radio frequency to a possible intermediate frequency as well as beamforming etc.

In one alternative, the radio part 120 and the baseband part 130 are situated on different application-specific integrated circuits (ASIC) on the same or different printed circuit boards within the same case. In another alternative, the radio part 120 and the baseband part 130 are parts of a distributed base station system and called Radio Unit (RU) and Distributed Unit (DU) or Baseband Unit (BBU), respectively, wherein the RU and the BBU/DU are geographically separated and interconnected via a fronthaul link. Thus, the network node 110 may be embodied as a node that comprises the radio part 120 but does not comprise the baseband part 130. Accordingly, the baseband part 130 may be embodied in another network node that is separate and apart from the network node (110) comprising the radio part 120.

In some embodiments, the network node 110 is an Open-RAN (ORAN) network node in an ORAN network that supports an ORAN specification (e.g., a specification published by the O-RAN Alliance, or any similar organization) and may operate alone or together with other nodes to implement one or more wireless communication functionalities (the adjective “open” designating support of an ORAN specification). Examples of an ORAN network node include an open radio unit (O-RU), an open distributed unit (O-DU), an open central unit (O-CU), including an O-CU control plane (O-CU-CP) or an O-CU user plane (O-CU-UP), a RAN intelligent controller (near-real time or non-real time) hosting software or software plug-ins, such as a near-real time control application (e.g., xApp) or a non-real time control application (e.g., rApp), or any combination thereof.

The radio part 120 has a wideband receiver (WBR) 122 for obtaining and processing wideband signals received at the antenna elements 111, 112. The radio part further has a narrowband receiver (NBR) 125 for obtaining and processing narrowband signals received at the antenna elements 111, 112. The wideband signals have a larger bandwidth than the narrowband signals. More specifically, the NBR 125 is a receiver that processes signals in a limited set of a total bandwidth, whereas the WBR 122 is a receiver that processes signals spanning the total bandwidth. In other words, the narrowband signals may be a subset of the wideband signals. The narrowband signals are typically transmitted with a lower data rate than the wideband signals. The wideband signals typically transmit payload whereas the narrowband signals typically transmit control data. For example, the NBR is designed to be used for receiving and processing PRACH, PUCCH, SRS and narrowband PUSCH. The receiving and processing of narrowband signals performed by the NBR 125 may be performed in parallel with the WBR 122 receiving and processing wideband signals. In some terminologies the narrowband signals are said to contain a channel or transmit a channel, such as a PRACH, PUSCH, SRS or PUSCH.

The network node 110, and more specifically the baseband part 130, is further connected to other nodes 160 of the wireless communication network, such as to other radio access network (RAN) nodes and to a core network.

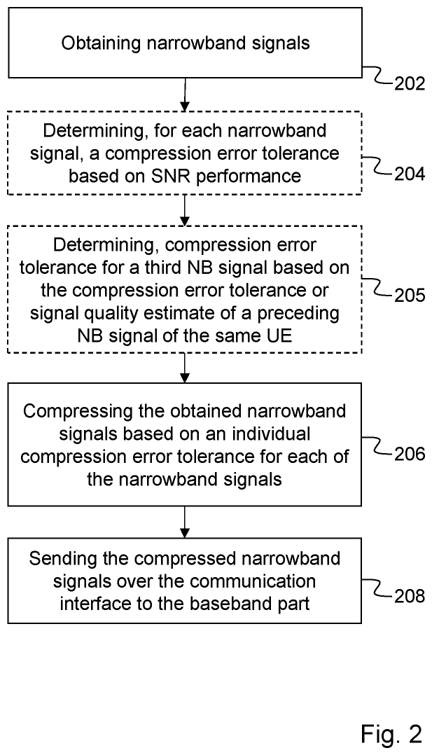

FIG. 2 in connection with FIG. 1 describes a method performed by a network node 110 of a wireless communication network. The network node 110 comprises a radio part 120 and a baseband part 130 connected to the radio part 120 via a communication interface 140. The network node 110 has a plurality of antennas 111, 112. The method comprises obtaining 202, by the radio part 120, narrowband signals received at each of the plurality of antennas 111, 112 from a number of UEs 150 wirelessly connected to the network node 110. The method further comprises compressing 206, by the radio part 120, the obtained narrowband signals of the plurality of antennas so that the compressed narrowband signals as a group contains fewer number of bits than the obtained narrowband signals, wherein the compression is performed based on an individual compression error tolerance for each of at least some of the obtained narrowband signals. The method further comprises sending 208, by the radio part 120, the compressed narrowband signals over the communication interface 140 to the baseband part 130.

By performing the compression based on an individual compression error tolerance for at least some of the narrowband signals, the narrowband signals can be compressed on an individual basis compared to for example a solution where all narrowband signals are compressed equally. Hereby, narrowband signals that have a higher compression error tolerance can be compressed to a higher degree than narrowband signals having a lower compression error tolerance. When all narrowband signals are compressed equally, the amount of compression has to be adapted to the narrowband signal having the lowest compression error tolerance. Thus, by the above solution, when the narrowband signals are sent over the communication interface 140 to the baseband part 130, capacity on the communication interface 140 can be saved. Hereby, the same interface capacity can cope with either more Physical Resource Blocks (PRBs) for sending of the narrowband signals or the narrowband signals can be transmitted with less delay. This is especially of interest when wideband signals and narrowband signals are transported over the communication interface 140 simultaneously so that they have to share the interface.

A narrowband signal can be one single antenna signal or a signal combined from a plurality of antenna signals. The (combined) narrowband signal could comprise a physical channel like PRACH/PUCCH/PUSCH/SRS. The communication interface 140 may be for example a cable, a conductor on an ASIC or between ASICS or a network such as an Ethernet network, etc. Compressing 206 of the obtained narrowband signals may signify using fewer bits for representing a narrowband signal after the compression compared to before the compression. This may be accomplished by e.g., using fewer quantization bits or lossy or lossless compression making use of correlation among samples to decrease the number of bits. Compressing may also signify limiting the number of antenna narrowband signals by deleting some of them considered not interesting. The term “the compressed narrowband signals as a group contains fewer number of bits than the obtained narrowband signals” covers all those alternatives. Compression error tolerance is a measure on how much compression the signal can cope with, for example before the signal is distorted over a threshold value.

The compressed narrowband signals may or may not be sent 208 over the communication interface 140 together with the wideband signals.

According to an embodiment, the method further comprises determining 204, for each of the at least some of the obtained narrowband signals, the individual compression error tolerance based on a signal quality performance for the narrowband signal, the signal quality performance being a measure of signal quality versus decoding error rate or detection error rate. The signal quality performance may be Signal to Noise Ratio (SNR) performance or Signal to Interference and Noise Ratio (SINR) performance. The signal on which a signal quality performance is made may be the narrowband signal. This measure is a good measure for estimating compression error tolerance. The determining 204 of compression error tolerance may be performed by the radio part 120. Alternatively, the determining 204 of compression error tolerance is performed in the baseband part 130 and communicated to the radio part 120 via the interface 140.

According to another embodiment, the signal quality performance is Signal to Noise Ratio, SNR, performance and the SNR performance is a known relation between the SNR and Block Error Rate, BLER, for the narrowband signal, or a known relation between the SNR and missed detection rate.

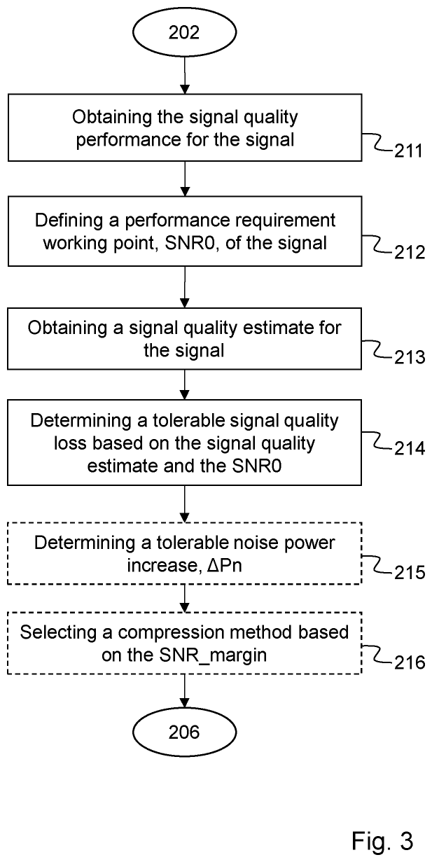

According to another embodiment, which is shown in FIG. 3, the determining 204 of compression error tolerance for each of the at least some of the narrowband signals comprises, for each signal: obtaining 211 the signal quality performance for the narrowband signal; defining 212 a performance requirement working point, SNR0, of the narrowband signal; obtaining 213 a signal quality estimate for the narrowband signal; and determining 214 a tolerable signal quality loss, SNR_margin, based on the signal quality estimate and the SNR0. Further, the compression 206 is performed based on the determined SNR_margin. This has proven to be a successful way of determining the compression error tolerance per narrowband signal. The signal quality mentioned above may be SNR or SINR for example. According to an alternative, the tolerable signal quality loss may also be determined 214 based on a signal quality loss limit, in addition to being determined based on the signal quality estimate and the SNR0.

According to another embodiment, the method further comprises determining 215 a tolerable noise power increase, ΔPn, based on a current noise power, Pn, and the SNR_margin. Further, the compression 206 is performed based on the ΔPn. Current noise power, Pn, can be estimated from a noise floor constant, e.g. Boltzmann's constant, or from a noise figure/factor, or it may be calculated directly from a reference signal sent in uplink.

According to yet another embodiment, the method further comprises selecting 216 a compression method, out of a plurality of different compression methods, to be used in the compression 206 based on the determined SNR_margin. The different compression methods out of which one compression method is selected may be e.g. Spatial reduction or Fewer quantization bits. Other possible selectable compression methods are picking signals from only some of the antennas/beams, picking signals from all antennas/beams while using less bits for quantization, picking signals from all antennas/beams and use normal quantization while picking a subset of the symbols, or picking signals from all antennas/beams and use normal quantization while applying time-domain or frequency-domain compression techniques to compress the data before transport. In case the tolerable noise power increase, ΔPn, was determined, the selection 216 may be made based on the ΔPn.

According to yet another embodiment, the signal quality estimate is an SNR estimate. Further, the SNR estimate is obtained 213 based on a signal power estimate and noise power estimate of the narrowband signal, based on used modulation and coding scheme, MCS, of the narrowband signal, based on power control information, based on SNR measured on a reference signal, or based on SNR statistics of earlier narrowband signals communicated between UEs and the network node 110.

According to yet another embodiment shown in FIG. 2, a first of the obtained narrowband signals carrying a first type of physical channel is determined to be compressed with same compression method and same compression level as a second of the obtained narrowband signals carrying a second type of physical channel, when the first and second narrowband signals are in the same narrowband receiver resource blocks. For example, the first type of physical channel may be a PRACH, and the second type of physical channel may be a PUCCH. When the first and second signal are in the same NBR resource blocks, it is determined that they are to be compressed at a same compression level and with the same compression method, i.e. in the same way.

According to yet another embodiment of FIG. 2, the method further comprises determining 205, compression error tolerance for a third of the obtained narrowband signals based on compression error tolerance or signal quality estimate of a fourth of the obtained narrowband signal preceding the third narrowband signal, the third and the fourth narrowband signals both relating to a first of the number of UEs 150. In other words, it has been found out that there is a coherence between narrowband signals or channels relating to the same UE, which signals or channels are adjacent in time.

For example, the SNR estimate of one narrowband signal or channel of one UE may be reused for a following signal or channel for the same UE. Specifically, the third narrowband signal may be a msg3 of the RACH procedure, and the fourth narrowband signal may be a PRACH, aka msg1. In other words, then the SNR estimate of the PRACH can be reused for determining the compression error tolerance for the msg3.

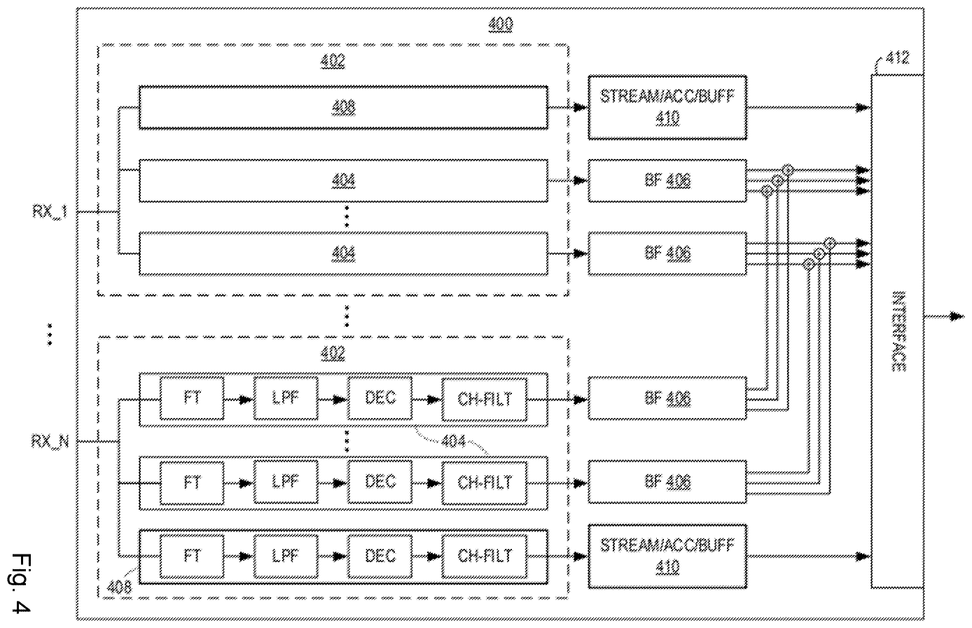

FIG. 4 illustrates an example of a digital portion 400 of a radio part 120 for handling wideband and narrowband signals. In the embodiment illustrated in FIG. 4, the digital portion 400 includes multiple signal processing blocks 402 representing complex (I+Q) signal processing, and each signal processing block 402 includes multiple carriers 404, each supplying a signal to a respective beamforming (BF) unit 406. The digital portion 400 also includes an additional Narrowband Receiver (NBR) 408. In the embodiment illustrated in FIG. 4, the structure, e.g., the signal processing chain, of the NBR 408 is the same as for the carrier paths 404, but the bandwidth of the added NBR 408 is less than the bandwidth for the other carrier paths 404, and so the carrier paths 404 may be referred to herein as Wideband Receivers (WBRs) 404. In some embodiments, the NBR 408 can capture one full carrier down to some fraction of a full carrier, e.g., one-fourth of a carrier, but other portions are also contemplated. Also, there is no BF of the narrowband receiver paths. Instead, that data is sent to the baseband part 130 for further processing, such as spatial DFT processing to determine beam directions.

In the embodiment illustrated in FIG. 4, there is an additional block 410 that can send the data to the CU immediately, e.g., via an interface 412, or buffer it for later sending, but in alternative embodiments that block may be omitted. In some embodiments which include block 410, block 410 can perform accumulation of data, such as data primarily used for PRACH reception.

In the embodiment illustrated in FIG. 4, both the WBRs and the NBRs comprise the following functional blocks, which may include circuitry to perform their particular functions: a Frequency Translation (FT) block, which is used to select the correct center frequency for the carrier extraction from the multi-carrier antenna signal RX; a Low Pass Filter (LPF); a Decimator (DEC); and a Channel Filter (CH-FILT). In this embodiment, the NBR has a signal processing pipeline that is similar to that used by the WBR, but with a narrower bandwidth.

In the following, embodiments of handling narrowband signals in an NBR of a radio part of a network node is described. A sample data stream contained in an UL antenna signal may have big redundancy because the amount of raw information transported by the data stream may be limited in many cases. This is especially true when it comes to narrowband signals, as the narrowband signals normally deliver PUSCH with low MCS or other low SNR channels. If all narrowband signals are sent over the communication interface 140 between the radio part 120 and the baseband part 130 uncompressed, the redundancy can lead to data of the narrowband signals being delayed when transmitted over the communication interface 140. The communication interface 140 may be a Common Public Radio Interface (CPRI) or an extended CPRI (eCPRI).

Consider the case when the narrowband signal contains a PRACH for example. The working point of a PRACH is normally at negative SNR (in dB), which is not sensitive to quantization error. At high SNR, since performance is very good anyway, quantization normally does not harm the detection either. Quantization error is normally independent and identically distributed over antenna branches, so its impact is close to Additive White Gaussian Noise (AWGN).

Output SNR, γ, of the matched filter in the PRACH detector when considering quantization noise is given by:

$$γ = \frac{2 E}{{N}_{0}} = \frac{{P}_{s} \cdot T \cdot B}{{P}_{n} + \frac{1}{12} {( \frac{k \sqrt{{P}_{s} + {P}_{n}}}{{2}^{L}} )}^{2}} = \frac{{γ}_{0} ( T \cdot B )}{1 + \frac{1}{12} {( \frac{k \sqrt{{γ}_{0} + 1}}{{2}^{L}} )}^{2}}$$

where Pₛ is input signal, Pₙ is noise power, B is noise bandwidth and T is signal duration. γ₀ is the SNR in absence of quantization noise when T·B=1.
Quantization noise is here modeled as

$$\frac{1}{12} {( \frac{k \sqrt{{P}_{s} + {P}_{n}}}{{2}^{L}} )}^{2} ,$$

where both signal and noise are Gaussian, which is normally true for Orthogonal Frequency-Domain Multiplexing (OFDM), and independent from the quantization noise. k is a factor to avoid clipping, L is number of quantization bits.

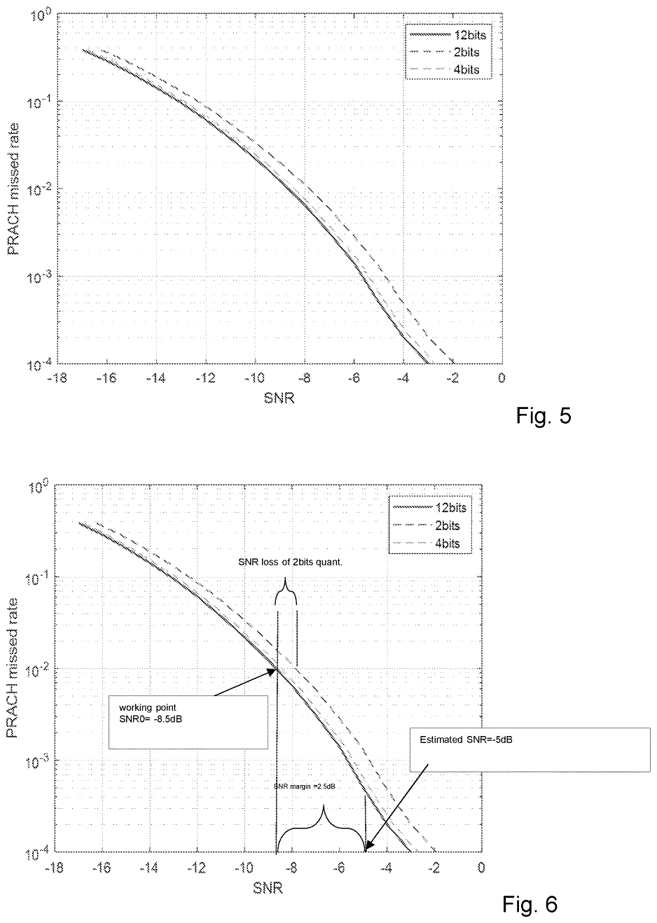

FIG. 5 shows the quantization impact on an example PRACH performance for k=3. The diagram of FIG. 4 shows missed detection rate on the PRACH in relation to SNR when using 2, 4 or 12 bits. As can be seen, decreasing the number of bits from 12 to 4 does not affect the missed rate, or at least very little. Even decreasing to 2 bits is not very harmful. Consequently, this PRACH has a high compression error tolerance, i.e., it can be compressed a lot without losing any significant detection performance.

Also, other rather robust channels have similar tolerance of quantization, e.g., PUCCH, which in many cases carries a few control bits with low order modulation. For the data channel, i.e. PUSCH, quantization error can impact more in case of high SNR. But it is still possible to determine a tolerable quantization noise level. Further, channels processed by NBR are sometimes with low-order modulation or low SNR. Similar to fewer quantization bits, some lossy data compression schemes can be employed if tolerance allows.

For flexible compression, i.e., a compression that is individual per narrowband signal, it is important to know to what extent data of the signal can be compressed. In the following, a method according to an embodiment for determining compression error tolerance for a narrowband signal is described. The method comprises five steps. Step 1 signifies obtaining SNR performance e.g. SNR vs. BLER curve, or SNR vs. missed detection rate curve, which can be known information for a certain product or product configuration. Step 2 signifies defining a working point of the signal. The working point can be an SNR level (SNR0) that corresponds to minimum or nominal performance requirement e.g. 10% BLER or 1% missed detection rate. Step 3 signifies obtaining an SNR estimate (estimated_SNR) of an input signal. The input signal can be a signal received from a certain antenna/beam/cable/logic channel/CPRI stream/IP connection. Step 4 signifies calculating a tolerable SNR loss (SNR_margin) and possibly also a tolerable noise power increase (ΔPn) as below:

$$SNR\_margin = max ( estimated\_SNR - SNR 0 , SNR\_loss \_limit ) ; // in dB$$

$$Δ {P}_{n} = Pn * 10 \hat{} ( SNR\_margin / 10 ) - Pn ;$$

The tolerable SNR loss and the tolerable noise power increase are examples of compression error tolerances. Note that SNR_loss_limit, i.e. minimum tolerable SNR loss, is intended to be a small value e.g. 0.2 dB, so that it does not harm traffic in an obvious way, while in case of low SNR can create remarkable noise power increase margin to allow higher compression error. The reason is that a certain noise power increase has less impact on a noise dominant signal than a high SNR signal. FIG. 6 illustrates the different terms above for the example PRACH shown in FIG. 5. The working point can be read to be −8.5 dB for 1% missed detection rate (PRACH missed rate). The estimated SNR, measured form the input signal, is −5 dB. The SNR_margin will then be −5−(−8.5)=3.5 dB as long as the SNR loss limit is lower than 3.5 dB.

Also note that it is possible to compress a high SNR signal remarkably, even though SNR loss is big, since only if the information can be restored correctly there is no problem with compression. For example, only if PRACH detection or PUCCH Hybrid Automatic Repeat Request (HARQ) bit decoding is correct, a SNR degradation up to (estimated_SNR-SNR0) is considered acceptable.

Step 5 signifies to select a compression method that matches the calculated SNR_margin or ΔPₙ. For example, either fewer quantization bits (noise increase) or Spatial Reduction (lower SNR) can be used for compression purpose.

An example of Spatial Reduction, which is especially advantageous at high SNR, is described in the following example: In certain symbols, NBR receives PUCCH channels from several UEs who all are situated rather close to the gNB and have high SNR. This scenario should be common specially with a hybrid beamforming system, where a time-domain elevation beam covers certain elevation slice at a given time to serve UEs in that elevation slice. In other words, UEs who belong to the same lower elevation slice can be scheduled in same symbol and they often all have high SNR. In those symbols, based on the min {calculated SNR_margin for each UE}, we can select and transfer received NBR data only from a subset of all the antennas/streams.

In the following, possible embodiments of step 3 above are described, i.e. how to obtain the SNR. According to one embodiment, the SNR estimation is obtained at a data compression component, based on estimated signal power and estimated noise level. For example, when receiving a PRACH at the NBR, there can be OFDM symbol level accumulation which will increase signal power. Such increase should be considered in signal power calculation. According to another embodiment, the SNR is estimated based on the used Modulation and Coding Scheme (MCS). MCS is known beforehand e.g., by a scheduler of the network node. According to another embodiment, the SNR is estimated based on power control information, which in turn is based on uplink (UL) measurements or UL power configuration. For example, target signal power configured at the network node can be used to estimate the true signal power. According to another embodiment, the SNR is measured on a received UL reference signal. According to yet another embodiment, the SNR is estimated from SNR statistics of different UE groups e.g., UEs located at cell edge can have different SNR from UEs at cell center. Further, UEs that are co-scheduled may have very different SNR statistics from non-co-scheduled UEs.

According to another embodiment, a compression level, or amount of compression when using a certain compression method, can be selected based on the type of channel of a narrowband signal. Different physical channels e.g., PRACH and PUCCH, can have different compression levels and possibly also use different compression methods if they belong to different NBR streams. In case they are transported by the same NBR stream they may use the same compression method and the same compression level of the compression method, while the compression level is determined by the channel with the smaller SNR margin. So, in other words, the two different channels being on the same NBR stream can be determined to use the same compression method and compression level, determined by the channel of the two channels with the lower compression error tolerance.

According to yet another embodiment, compression level, i.e. amount of compression of a certain compression method, for one channel of a narrowband signal is determined based on a compression level of another channel of a narrowband signal that is adjacent in time. According to a first example, which is for a RACH procedure, an SNR estimate of a PRACH, i.e. a RACH preamble, can be used for determining msg3 PUSCH compression of the same user. Because the msg3 has a known MCS and power, the compression error tolerance can be determined in advance, when using the SNR estimate of the PRACH. Msg3 transmission power is known in advance as the PRACH power is taken as reference and added with a power offset, which is called msg3-DeltaPreamble, in 3GPP, see e.g. TS 38.213 version 15.8.0 “Physical layer procedures for control” chapter 7.1.1 page 15. According to a second example, physical channels close in time, e.g. in terms of slot/symbol, from the same UE can have same/similar compression level. Rationale is that adjacent slots experience similar fading and also similar UE power. Note that co-scheduled or multiplexed channels, such as PUCCH or PUSCH, should use the same compression level, which should be based on the smallest compression error tolerance among multiplexed UEs.

According to another embodiment, measurement statistics are used to determine compression error tolerance and thereby compression level. The measurement statistics can be for one or more UEs. The statistics can be a performance indicator, such as a detection error rate, e.g. BLER. If the current BLER statistics is far below a BLER target, e.g., 1% versus 10%, then the compression error tolerance is probably high also for the current narrowband signal and there should be a good margin for further compression. Another possible measurement statistics that could indicate compression error tolerance is characteristic of an intermediate signal in a processing chain of the NBR, e.g. a de-mapping Error Vector Magnitude (EVM) estimation.

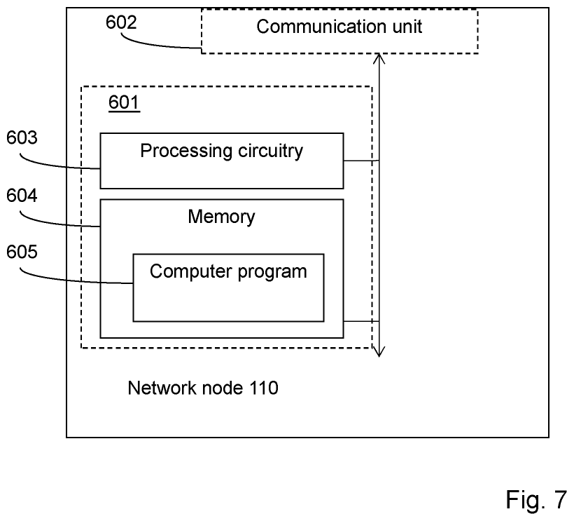

FIG. 7, in conjunction with FIG. 1, shows a network node 110 of a wireless communication network 100, the network node 110 comprising a radio part 120 and a baseband part 130 interconnected via a communication interface 140. The network node 110 has a plurality of antennas 111, 112. The network node 110 comprises a processing circuitry 603 and a memory 604. Said memory contains instructions executable by said processing circuitry, whereby the network node 110 is operative for obtaining, by the radio part 120, narrowband signals received at each of the plurality of antennas 111, 112 from a number of User Equipment, UE 150, wirelessly connected to the network node 110. The network node is further operative for compressing, by the radio part 120, the obtained narrowband signals of the plurality of antennas so that the compressed narrowband signals as a group contains fewer number of bits than the obtained narrowband signals, wherein the compression is performed based on an individual compression error tolerance for each of at least some of the obtained narrowband signals, and sending, by the radio part 120, the compressed narrowband signals over the communication interface 140 to the baseband part 130.

According to an embodiment, the network node 110 is further operative for determining, for each of the at least some of the obtained narrowband signals, the individual compression error tolerance based on a signal quality performance for the narrowband signal, the signal quality performance being a measure of signal quality versus decoding error rate or detection error rate.

According to an embodiment, the signal quality performance is Signal to Noise Ratio (SNR) performance and the SNR performance is a known relation between the SNR and Block Error Rate (BLER) for the narrowband signal, or a known relation between the SNR and missed detection rate.

According to another embodiment, the network node 110 is operative for the determining of compression error tolerance for each of the at least some of the narrowband signals by, for each signal, obtaining the signal quality performance for the narrowband signal, defining a performance requirement working point (SNR0) of the narrowband signal, obtaining a signal quality estimate for the narrowband signal, and determining a tolerable signal quality loss (SNR_margin) based on the signal quality estimate and the SNR0. Further, the network node is operative for performing the compression based on the determined SNR_margin.

According to another embodiment, the network node 110 is further operative for determining a tolerable noise power increase, ΔPn, based on a current noise power, Pn, and the SNR_margin. Further, the network node is operative for performing the compression based on the ΔPn.

According to yet another embodiment, the network node 110 is further operative for selecting a compression method, out of a plurality of different compression methods, to be used in the compression based on the determined SNR_margin.

According to yet another embodiment, the signal quality estimate is an SNR estimate. Further, the network node 110 is operative to obtain the SNR estimate based on a signal power estimate and noise power estimate of the narrowband signal, based on used modulation and coding scheme, MCS, of the narrowband signal, based on power control information, based on SNR measured on a reference signal, or based on SNR statistics of earlier narrowband signals communicated between UEs and the network node 110.

According to yet another embodiment, the network node 110 is operative for determining that a first of the obtained narrowband signals carrying a first type of physical channel is to be compressed with same compression method and same compression level as a second of the obtained narrowband signals carrying a second type of physical channel when the first and second narrowband signals are in the same narrowband receiver resource blocks.

According to still another embodiment, the network node 110 is further operative for determining compression error tolerance for a third of the obtained narrowband signals based on compression error tolerance or signal quality estimate of a fourth of the obtained narrowband signal preceding the third narrowband signal, the third and the fourth narrowband signals both relating to a first of the number of UEs 150.

According to another embodiment, the network node 110 is operative for performing the compressing dynamically over time based on the individual compression error tolerance.

According to other embodiments, the network node 110 may further comprise a communication unit 602, which may be considered to comprise conventional means for wireless communication with the wireless device 150, such as a transceiver for wireless transmission and reception of signals in the communication network. The communication unit 602 may also comprise conventional means for communication with other network nodes of the wireless communication network, such as other RAN nodes 160. The instructions executable by said processing circuitry 603 may be arranged as a computer program 605 stored e.g. in said memory 604. The processing circuitry 603 and the memory 604 may be arranged in a sub-arrangement 601. The sub-arrangement 601 may be a micro-processor and adequate software and storage therefore, a Programmable Logic Device, PLD, or other electronic component(s)/processing circuit(s) configured to perform the methods mentioned above. The processing circuitry 603 may comprise one or more programmable processor, application-specific integrated circuits, field programmable gate arrays or combinations of these adapted to execute instructions.

The computer program 605 may be arranged such that when its instructions are run in the processing circuitry, they cause the network node 110 to perform the steps described in any of the described embodiments of the network node 110 and its method. The computer program 605 may be carried by a computer program product connectable to the processing circuitry 603. The computer program product may be the memory 604, or at least arranged in the memory. The memory 604 may be realized as for example a RAM (Random-access memory), ROM (Read-Only Memory) or an EEPROM (Electrical Erasable Programmable ROM). In some embodiments, a carrier may contain the computer program 605. The carrier may be one of an electronic signal, an optical signal, an electromagnetic signal, a magnetic signal, an electric signal, a radio signal, a microwave signal, or computer readable storage medium. The computer-readable storage medium may be e.g. a CD, DVD or flash memory, from which the program could be downloaded into the memory 604. Alternatively, the computer program may be stored on a server or any other entity to which the network node 110 has access via the communication unit 602. The computer program 605 may then be downloaded from the server into the memory 604.

Although the description above contains a plurality of specificities, these should not be construed as limiting the scope of the concept described herein but as merely providing illustrations of some exemplifying embodiments of the described concept. It will be appreciated that the scope of the presently described concept fully encompasses other embodiments which may become obvious to those skilled in the art, and that the scope of the presently described concept is accordingly not to be limited. Reference to an element in the singular is not intended to mean “one and only one” unless explicitly so stated, but rather “one or more.” All structural and functional equivalents to the elements of the above-described embodiments that are known to those of ordinary skill in the art are expressly incorporated herein by reference and are intended to be encompassed hereby. Moreover, it is not necessary for an apparatus or method to address each and every problem sought to be solved by the presently described concept, for it to be encompassed hereby. In the exemplary figures, a broken line generally signifies that the feature within the broken line is optional.

1. A method performed by a network node of a wireless communication network, the network node comprising a radio part and a baseband part connected to the radio part via a communication interface, the network node having a plurality of antennas, the method comprising:
obtaining, by the radio part, narrowband signals received at each of the plurality of antennas from a number of User Equipment, UE, wirelessly connected to the network node;
compressing, by the radio part, the obtained narrowband signals of the plurality of antennas so that the compressed narrowband signals as a group contains fewer number of bits than the obtained narrowband signals, wherein the compression is performed based on an individual compression error tolerance for each of at least some of the obtained narrowband signals, and
sending, by the radio part, the compressed narrowband signals over the communication interface to the baseband part.

2. The method according to claim 1, further comprising:
determining, for each of the at least some of the obtained narrowband signals, the individual compression error tolerance based on a signal quality performance for the narrowband signal, the signal quality performance being a measure of signal quality versus decoding error rate or detection error rate.

3. The method according to claim 2, wherein the signal quality performance is Signal to Noise Ratio, SNR, performance and the SNR performance is a known relation between the SNR and Block Error Rate, BLER, for the narrowband signal, or a known relation between the SNR and missed detection rate.

4. The method according to claim 2, wherein the determining of compression error tolerance for each of the at least some of the narrowband signals comprises, for each signal:
obtaining the signal quality performance for the narrowband signal;
defining a performance requirement working point, SNR0, of the narrowband signal;
obtaining a signal quality estimate for the narrowband signal;
determining a tolerable signal quality loss, SNR_margin, based on the signal quality estimate and the SNR0,
and wherein the compression is performed based on the determined SNR_margin.

5. The method according to claim 4, further comprising:
determining a tolerable noise power increase, ΔPn, based on a current noise power, Pn, and the SNR_margin, and wherein the compression is performed based on the ΔPn.

6. The method according to claim 4, further comprising:
selecting a compression method, out of a plurality of different compression methods, to be used in the compression based on the determined SNR_margin.

7. The method according to claim 4, wherein the signal quality estimate is an SNR estimate, and wherein the SNR estimate is obtained based on a signal power estimate and noise power estimate of the narrowband signal, based on used modulation and coding scheme, MCS, of the narrowband signal, based on power control information, based on SNR measured on a reference signal, or based on SNR statistics of earlier narrowband signals communicated between UEs and the network node.

8. The method according to claim 1, wherein a first of the obtained narrowband signals carrying a first type of physical channel is determined to be compressed with same compression method and same compression level as a second of the obtained narrowband signals carrying a second type of physical channel when the first and second narrowband signals are in the same narrowband receiver resource blocks.

9. The method according to claim 1, further comprising:
determining compression error tolerance for a third of the obtained narrowband signals based on compression error tolerance or signal quality estimate of a fourth of the obtained narrowband signal preceding the third narrowband signal, the third and the fourth narrowband signals both relating to a first of the number of UEs.

10. The method according to claim 1, wherein the compressing is performed dynamically over time based on the individual compression error tolerance.

11. A network node of a wireless communication network, the network node comprising a radio part and a baseband part interconnected via a communication interface, the network node having a plurality of antennas, the network node comprising a processing circuitry and a memory, the memory containing instructions executable by the processing circuitry, the network node is being operative to:
obtain, by the radio part, narrowband signals received at each of the plurality of antennas from a number of User Equipment, UE, wirelessly connected to the network node;
compress, by the radio part, the obtained narrowband signals of the plurality of antennas so that the compressed narrowband signals as a group contains fewer number of bits than the obtained narrowband signals, wherein the compression is performed based on an individual compression error tolerance for each of at least some of the obtained narrowband signals, and
send, by the radio part, the compressed narrowband signals over the communication interface to the baseband part.

12. The network node according to claim 11, being further operative to:
determine, for each of the at least some of the obtained narrowband signals, the individual compression error tolerance based on a signal quality performance for the narrowband signal, the signal quality performance being a measure of signal quality versus decoding error rate or detection error rate.

13. The network node according to claim 12, wherein the signal quality performance is Signal to Noise Ratio, SNR, performance and the SNR performance is a known relation between the SNR and Block Error Rate, BLER, for the narrowband signal, or a known relation between the SNR and missed detection rate.

14. The network node according to claim 12, being operative to determine the compression error tolerance for each of the at least some of the narrowband signals by, for each signal:
obtaining the signal quality performance for the narrowband signal;
defining a performance requirement working point, SNR0, of the narrowband signal;
obtaining a signal quality estimate for the narrowband signal; and
determining a tolerable signal quality loss, SNR_margin, based on the signal quality estimate and the SNR0,
and wherein the network node is operative for performing the compression based on the determined SNR_margin.

15. The network node according to claim 14, being further operative to:
determine a tolerable noise power increase, ΔPn, based on a current noise power, Pn, and the SNR_margin,
and wherein the network node is operative to perform the compression based on the ΔPn.

16. The network node according to claim 14, being further operative for to:
select a compression method, out of a plurality of different compression methods, to be used in the compression based on the determined SNR_margin.

17. The network node according to claim 14, wherein the signal quality estimate is an SNR estimate, and wherein the network node is operative to obtain the SNR estimate based on a signal power estimate and noise power estimate of the narrowband signal, based on used modulation and coding scheme, MCS, of the narrowband signal, based on power control information, based on SNR measured on a reference signal, or based on SNR statistics of earlier narrowband signals communicated between UEs and the network node.

18. The network node according to claim 11, operative to determine that a first of the obtained narrowband signals carrying a first type of physical channel is to be compressed with same compression method and same compression level as a second of the obtained narrowband signals carrying a second type of physical channel when the first and second narrowband signals are in the same narrowband receiver resource blocks.

19. The network node according to claim 11, being further operative to determine compression error tolerance for a third of the obtained narrowband signals based on compression error tolerance or signal quality estimate of a fourth of the obtained narrowband signal preceding the third narrowband signal, the third and the fourth narrowband signals both relating to a first of the number of UEs.

20. (canceled)

21. A computer storage medium storing a computer program comprising instructions, which, when executed by at least one processing circuitry of a network node of a wireless communication network, the network node comprising a radio part and a baseband part interconnected via a communication interface, the network node having a plurality of antennas, causes the network node to:
obtain, by the radio part, narrowband signals received at each of the plurality of antennas from a number of User Equipment, UE, wirelessly connected to the network node;
compress, by the radio part, the obtained narrowband signals of the plurality of antennas so that the compressed narrowband signals as a group contains fewer number of bits than the obtained narrowband signals, wherein the compression is performed based on an in dividual compression error tolerance for each of at least some of the obtained narrowband signals, and
send, by the radio part, the compressed narrowband signals over the communication interface to the baseband part.

22. (canceled)
